(19) United States
(12) Patent Application Publication
(10) Pub. No.: US 2022/0044949 A1
(43) Pub. Date: Feb. 10, 2022

(54) INTERACTIVE AND ITERATIVE TRAINING OF A CLASSIFICATION ALGORITHM FOR CLASSIFYING ANOMALIES IN IMAGING DATASETS

(71) Applicant: Carl Zeiss SMT GmbH, Oberkochen (DE)

(72) Inventors: Thomas Korb, Schwaebisch Gmuend (DE); Philipp Huethwohl, Ulm (DE); Jens Timo Neumann, Aalen (DE); Abhilash Srikantha, Neu-Ulm (DE)

(21) Appl. No.: 17/376,664

(22) Filed: Jul. 15, 2021

(30) Foreign Application Priority Data
Aug. 6, 2020 (DE) 102020120781.6

(51) Int. Cl. H01L 21/67; G06F 16/28; G06N 3/08; G06T 7/00; G06K 9/62

(52) U.S. Cl. CPC H01L 21/67288; G06F 16/285; G06N 3/088; G06T 7/0004; G06K 9/628; G06K 9/6256; G06T 2207/10061; G06K 9/6218; G06K 9/6253; G06T 2207/30148; G06T 2207/20081; G06T 2207/20092; G06K 9/6215

(57) ABSTRACT

A method includes detecting a plurality of anomalies in an imaging dataset of a wafer. The wafer includes a plurality of semiconductor structures. The method also includes executing multiple iterations. At least some of the iterations include determining a current classification of the plurality of anomalies using a machine-learned classification algorithm and tiles of the imaging dataset associated with the plurality of anomalies. The current classification includes a current set of classes into which the anomalies of the plurality of anomalies are binned. The method further includes, based on at least one decision criterion, selecting at least one anomaly of the plurality of anomalies for a presentation to a user. In addition, the method includes, based on an annotation of the at least one anomaly provided by the user with respect to the current classification, re-training the classification algorithm.

### CROSS-REFERENCE TO RELATED APPLICATION

This application claims benefit under 35 U.S.C. § 119 to German Application No. 10 2020 120 781.6, filed Aug. 6, 2020. The contents of this application is hereby incorporated by reference in its entirety.

### FIELD

Various examples of the disclosure generally relate to classifying anomalies in imaging datasets, e.g., imaging datasets of a wafer including a plurality of semiconductor structures. Various examples of the disclosure specifically relate to training a respective classification algorithm.

### BACKGROUND

In the fabrication of semiconductor devices, inspection of the wafer on which the semiconductor devices are structured is helpful. Thereby, defects of semiconductor structures forming the semiconductor devices can be detected.

Detection and classification of defects in such imaging datasets can involve significant time when executed according to reference techniques. This is, for example, true for multi-resolution imaging datasets that provide multiple magnification scales on which defects can be encountered. Further, the sheer number of semiconductor structures on a wafer can make it cumbersome to detect defects.

Conventionally, inspection of such imaging data can rely on machine-learned classification algorithms. Such classification algorithms can be trained based on manual annotation of sample tiles of the imaging data. Such annotation of defects by a user can be very laborious on a large imaging data set and can bear the risk of not being done properly. In this case, the representation of defects can be incomplete, defects can be missed or misclassified, or a high number of false positive detections (nuisance) may not properly filtered out from the detected anomalies.

### SUMMARY

The disclosure seeks to provide advanced techniques of detection and classification of defects in imaging datasets.

A method includes detecting a plurality of anomalies. The plurality of anomalies is detected in an imaging dataset of a wafer including a plurality of semiconductor structures. The method also includes executing multiple iterations. At least some iterations of the multiple iterations include determining a current classification of the plurality of anomalies. The current classification is determined using a machine-learned classification algorithm and tiles of the imaging dataset associated with the plurality of anomalies. The current classification then includes a current set of classes into which the anomalies of the plurality of anomalies are binned. The at least some iterations also include selecting at least one anomaly of the plurality of anomalies for a presentation to the user. This selecting is based on at least one decision criterion. Then, the at least some iterations also include retraining the classification algorithm based on an annotation of the at least one anomaly. The annotation is provided by the user and is with respect to the current classification.

A computer program or a computer-program product or a computer-readable storage medium includes program code. The program code can be loaded and executed by at least one processor. Upon executing the program code, the at least one processor performs a method. The method includes detecting a plurality of anomalies. The plurality of anomalies is detected in an imaging dataset of a wafer including a plurality of semiconductor structures. The method also includes executing multiple iterations. At least some iterations of the multiple iterations include determining a current classification of the plurality of anomalies. The current classification is determined using a machine-learned classification algorithm and tiles of the imaging dataset associated with the plurality of anomalies. The current classification then includes a current set of classes into which the anomalies of the plurality of anomalies are binned. The at least some iterations also include selecting at least one anomaly of the plurality of anomalies for a presentation to the user. This selecting is based on at least one decision criterion. Then, the at least some iterations also include retraining the classification algorithm based on an annotation of the at least one anomaly. The annotation is provided by the user and is with respect to the current classification.

A device includes a processor. The processor can load and execute program code. Upon loading and executing the program code, the processor performs a method. The method includes detecting a plurality of anomalies. The plurality of anomalies is detected in an imaging dataset of a wafer including a plurality of semiconductor structures. The method also includes executing multiple iterations. At least some iterations of the multiple iterations include determining a current classification of the plurality of anomalies. The current classification is determined using a machine-learned classification algorithm and tiles of the imaging dataset associated with the plurality of anomalies. The current classification then includes a current set of classes into which the anomalies of the plurality of anomalies are binned. The at least some iterations also include selecting at least one anomaly of the plurality of anomalies for a presentation to the user. This selecting is based on at least one decision criterion. Then, the at least some iterations also include retraining the classification algorithm based on an annotation of the at least one anomaly. The annotation is provided by the user and is with respect to the current classification.

It is to be understood that the features mentioned above and those yet to be explained below may be used not only in the respective combinations indicated, but also in other combinations or in isolation without departing from the scope of the disclosure.

### BRIEF DESCRIPTION OF THE DRAWINGS

FIG. 1 schematically illustrates a system including an imaging device and a processing device according to various examples.

FIG. 2 is a flowchart of a method according to various examples.

FIG. 3 is a flowchart of a method according to various examples.

FIG. 4 is a schematic illustration of a user interface configured for batch annotation of multiple anomalies according to various examples.

FIGS. 5-11 schematically illustrate classification of multiple anomalies in selection of anomalies for presentation to the user for annotation according to various examples.

FIG. 12 is a flowchart of a method according to various examples.

FIG. 13 schematically illustrates the achievable increase and precision based on a 2-step approach including anomaly detection and classification of anomalies according to various examples.

FIG. 14 is a flowchart of a method according to various examples.

### DETAILED DESCRIPTION OF EMBODIMENTS

Some examples of the present disclosure generally provide for a plurality of circuits or other electrical devices. All references to the circuits and other electrical devices and the functionality provided by each are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microcontrollers, a graphics processor unit (GPU), integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a program code that is embodied in a non-transitory computer readable medium programmed to perform any number of the functions as disclosed.

In the following, embodiments of the disclosure will be described in detail with reference to the accompanying drawings. It is to be understood that the following description of embodiments is not to be taken in a limiting sense. The scope of the disclosure is not intended to be limited by the embodiments described hereinafter or by the drawings, which are taken to be illustrative only.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof. Cloud processing would be possible. In-premise and out-of-premise computing is conceivable.

Hereinafter, various techniques will be described that facilitate detection and classification of anomalies in an imaging dataset. The imaging dataset can, e.g., pertain to a wafer including a plurality of semiconductor structures. Other information content is possible, e.g., in imaging dataset including biological samples, e.g., tissue samples, optical devices such as glasses, mirrors, etc., to give just a few examples. Hereinafter, various examples will be described in the context of an imaging dataset that includes a wafer including a plurality of semiconductor structures, but similar techniques may be readily applied to other use cases.

According to various techniques, this can be based on a classification algorithm that classifies anomalies previously detected in the imaging dataset. For instance, the classification algorithm can classify an anomaly to be a defect or not. An anomaly can generally pertain to a localized deviation of the imaging dataset from an a priori defined norm. A defect can generally pertain to a deviation of a semiconductor structure or another imaged sample from an a priori defined norm. For instance, a defect of a semiconductor structure could result in malfunctioning of an associated semiconductor device.

In general, the classification can pertain to extracting actionable information for the anomalies. This can pertain to binning the anomalies into classes. It would also include classification of size, shape, and/or 3-D reconstruction, etc. More generally, one or more physical properties of the anomalies may be determined by the classification algorithm. In general, a so-called open-set classification algorithm can be used. Here, it is possible that the set of classes is not a fixed parameter, but can vary over the course of training of the ML classification algorithm.

Furthermore, an ML classification algorithm can be used that can handle uncertainty in the labels annotated by the user. Thus, it may not be assumed that the labelling is exact, i.e., each anomaly obtains a single exact label.

In general, not all anomalies are defects: for instance, anomalies can also include, e.g., imaging artefacts, variations of the semiconductor structures within the norm, etc. Such anomalies that are not defects but detected by some anomaly detection method can be referred to as nuisance. Typically, an anomaly detection will yield anomalies in the imaging dataset that include, both, defects, as well as nuisance.

According to the techniques described herein, it is possible to discriminate defects from nuisance. Furthermore, according to the techniques described herein, it is possible to accurately classify the defects. For illustration, multiple defect classes could be defined.

The classification algorithm could bin anomalies into different classes of a respective set of classes, wherein different classes of the set of classes pertain to different types of defects and/or discriminate nuisance from defects.

Such techniques of detection and classification of defects can be helpful in various use cases. One example use cases the Process Window Qualification: here, dies on a wafer are produced with varying production parameters, e.g., exposure time, focus variation, etc. Optimized production parameters can be identified based on a distribution of the defects across different regions of the wafer, e.g., across different dies of the wafer. This is only one example use case. Other use cases include, e.g., end of line testing.

According to the techniques described herein, various imaging modalities may be used to acquire an imaging dataset for detection and classification of defects. Along with the various imaging modalities, it would be possible to obtain different imaging data sets. For instance, it would be possible that the imaging dataset includes 2-D images. Here, it would be possible to employ a multibeam-scanning electron microscope (mSEM). mSEM employs multiple beams to acquire contemporaneously images in multiple fields of view. For instance, number of not less than 50 beams could be used or even not less than 90 beams. Each beam covers a separate portion of a surface of the wafer. Thereby, a large imaging dataset is acquired within a short duration. Typically, 4.5 gigapixels are acquired per second. For illustration, one square centimeter of a wafer can be imaged with 2 nm pixel size leading to 25 terapixel of data. Other examples for imaging data sets including 2D images would relate imaging modalities such as optical imaging, phase-contrast imaging, x-ray imaging, etc. It would also be possible that the imaging dataset is a volumetric 3-D dataset. Here, a crossbeam imaging device including a focused-ion beam source and a SEM could be used. Multimodal imaging datasets may be used, e.g., a combination of x-ray imaging and SEM.

Typically, machine-learning (ML) classification algorithms involve, for training, annotated examples. Creating a training dataset including annotated examples as ground truth often involves extensive manual annotation effort.

Furthermore, typically, the number of classes of a set of classes into which the anomalies provided as an input to the classification algorithm are binned is fixed.

Various techniques are based on the finding that, both, extensive manual annotation, as well as a fixed set of classes can be difficult to implement for imaging datasets of a wafer including semiconductor structures. This is because of the size of such imaging datasets and the variability in the possible defect classes. It is oftentimes not possible to define the set of classes beforehand.

Accordingly, various techniques described herein help to minimize human effort and pros vide flexibility in the classification of defects. In other words, given a large pool of tiles of the imaging dataset pertaining to anomalies, the aim is to appropriately bin these anomalies into classes with minimized human effort.

To achieve this task, an iterative refinement of the ML classification algorithm is implemented by re-training the ML classification algorithm in multiple iterations with continued user interaction. Per iteration, at least one anomaly is selected for a presentation to the user. Then, the selected at least one anomaly can be annotated by the user. Such annotation can be associated with manually binning the at least one anomaly into a class preexisting in the set of classes or adding a new class to the set of classes to which the selected at least one anomaly is binned.

By such iterative refinement of the ML classification algorithm, the following effects can be achieved: (i) The classification can be agnostic of the defect class. I.e., the ML classification algorithm can generalize to new datasets and defect classes without manual retuning. (ii) The classification can be interactive. I.e., the ML classification algorithm can accommodate user feedback for classification of anomalies. In other words, the application engineer can drive, adapt, and/or improve the functionality of the ML classification algorithm with minimum annotation effort. (iii) The training of the ML classification algorithm can be explorative: it is possible to propose anomalies that are difficult to classify into the pre-existing set of classes to the user and it is then possible to potentially add new classes to the pre-existing set of classes. (iv) The training of the ML classification algorithm can be exploitative: it is possible to automatically assign easy candidates of anomalies to known classes within the predefined set of classes, thereby reducing time for analysis of the anomalies. (v) Trackable metrics: metrics of the behavior of the ML classification algorithm can be monitored. Example metrics may include, e.g., the number of defect classes and the set of defect classes, the portion of anomalies explored, (worst) classification confidence of still unlabeled anomalies, etc. Based on such tracking of the performance of the ML classification algorithm, the iterative refinement of the ML classification algorithm can be aborted. In other words, one or more abort criteria may be defined depending on a performance of the ML classification algorithm that is determined based on such metric.

Various techniques employ a 2-step approach: in a first step, one or multiple anomalies are identified in an imaging dataset. For example, image tiles can be extracted from the imaging dataset that image the respective anomaly and a surrounding thereof. In a second step, the one or more anomalies can be classified using a ML classification algorithm. The ML classification algorithm can operate based on the imaging dataset, or more specifically on the image tiles that are extracted from the imaging dataset that image the respective anomaly and its surrounding. The ML classification algorithm can be iteratively trained based on manual annotations of anomalies provided by the user. This can be an interactive process, i.e., as the training process progresses, the anomalies selected for presentation to the user can be interactively adapted based on the user feedback from a previous iteration. In further detail, this means that based on the user feedback, the ML classification algorithm can be retrained. Then, the classification of the retrained ML classification algorithm will change and, accordingly, also the one or more selected anomalies to be presented to the user in the next iteration will change along with the change in the classification (this is because the one or more anomalies that are selected are selected based on the classification, at least in some iterations of the iterative training). Thus, e.g., based on an explorative and/or exploitative annotation scheme, the training of the ML classification algorithm is interactive.

In general, various types of algorithms may be used for the anomaly detection. For example, die-to-die or die-to-database comparisons could be made. The die-to-die comparison can detect a variability between multiple dies on the wafer. The die-to-database can detect a variability with respect to, e.g., a CAD file, e.g., defining a wafer mask. According to further examples, to detect the plurality of anomalies, an ML anomaly detection algorithm can be used. For instance, the ML anomaly detection algorithm can include an autoencoder neural network. Such autoencoder neural network can include an encoder neural network and a decoder neural network sequentially arranged. The encoder neural network can determine an encoded representation of an input tile of the imaging dataset and the decoder neural network can operate based on that encoded representation (a sparse representation of the input tile) to obtain a reconstructed representation of the input tile. The encoder neural network and the decoder neural network can be trained so as to minimize a difference between the reconstructed representation of the input tile and the input tile itself. After training, during inference, a comparison between the reconstructed representation of the input tile and the input tile can be in good correspondence—i.e., no anomaly detected—or can yield reduced correspondence—i.e., anomaly detected.

In some examples, a multi-stage approach may be used to detect the anomalies. For example, in a first stage, it would be possible to detect a candidate set of anomalies, e.g., using a die-to-die or die-to-database registration. In a second step, the candidate set of anomalies may be filtered based on the ML anomaly detection.

As will be appreciated from the above, this corresponds to training a pattern-encoding scheme. Such training is not significantly influenced by locally restricted, rarely occurring patterns (anomalies), because skipping them has no major impact on the overall reconstruction error, i.e., a value of the loss function considered during training.

In general, tiles (e.g., 2-D images or 3-D voxel arrays) extracted from the input dataset and input to the anomaly detection algorithm can include a sufficient spatial context of the anomaly to be detected. Respective tiles should be at least as large as the expected anomaly, but also incorporate a spatial neighborhood context, e.g., 32×32 pixels of 2 nm size to find anomalies of 10×10 pixels or less. For example, the neighborhood may be defined in the length scale of the semiconductor structures included in the imaging dataset. For instance, the semiconductor structure of a feature size of 10 nm, then the surrounding may include, e.g., an area of 30 nm×30 nm. Training such an autoencoder can take several hours or days on a high-performance GPU.

Then, the autoencoder (or more generally another anomaly detection algorithm), during inference, operates based on a tile that includes (i.e., depicts) an anomaly and optionally its surrounding. The reconstructed representation of the input tile will significantly differ from the input tile itself, because the training of the autoencoder is not significantly impacted by the anomaly which is therefore not included in the reconstructed representation. Hence, any difference between the input image and the reconstructed representation of the input image indicates an anomaly. A distance metric between the input image and the reconstructed representation of the input image can be used to quantify whether an anomaly is present. Typically, inference using the autoencoder only takes a few milliseconds.

Various techniques are based on the finding that such a process to detect anomalies can lead to a significant number of nuisances, i.e., anomalies that are not defects, but rather intentional features of the semiconductor structures or, e.g., imaging artifacts. This can be due to variance introduced by the wafer production process as well as the imaging process, leading to complex or random effects that are present in the imaging dataset. Therefore, the anomaly detection is followed by the ML classification algorithm. The ML classification algorithm can also help to classify different types of defects.

Next, details with respect to the ML classification algorithm are described.

According to the techniques described herein, a cold start of the ML classification algorithm is possible. I.e., the ML classification algorithm is not required to be pre-trained. For illustration, in a first iteration of the multiple iterations, it would be possible to perform an unsupervised clustering of the plurality of anomalies. The at least one anomaly for presentation is then selected based on the unsupervised clustering.

In general, the unsupervised clustering may differ from the classification in that it is not possible to refine a similarity measure underlying the unsupervised clustering based on a ML training. For example, manual parameterization of the unsupervised clustering may be possible. Therefore, the unsupervised clustering is suited to be used at the beginning the training of the ML classification algorithm. In other examples, the ML classification algorithm can be pre-trained, e.g., based on an imaging dataset of a further wafer including further semiconductor structures that have comparable features as the semiconductor structures of the wafer depicted by the imaging dataset, or even share such features.

In yet a further example, it would be possible that the ML classification algorithm is pretrained using a candidate annotation obtained from a pre-classification that is provided by another classification algorithm, e.g., a conventional non-ML classification algorithm.

In any case, the ML classification algorithm can then be adjusted/refined to accurately classify the anomalies, e.g., into one or more defect classes and nuisance.

To train the ML classification algorithm, multiple iterations are executed. At least some of these iterations include determining a current classification of the plurality of anomalies using the ML classification algorithm (in its current training state) and the tiles of the imaging dataset associated with the plurality of anomalies as obtained from the previous step of the 2-step approach. Then, based on at least one decision criterion, at least one anomaly is selected for a presentation to the user. Based on an annotation of the at least one anomaly provided by the user, the classification algorithm is retrained. Then, the next iteration can commence.

The classifications of the plurality of anomalies correspond to binning/assigning of the anomalies of the plurality of anomalies into a set of classes. Some of these classes may be so-called “defect classes”, i.e., denote different types of defects of the semiconductor structures. One or more classes may pertain to nuisance. There may be a further class that bins unknown anomalies, i.e., anomalies that do not have a good match with any of the remaining classes (“unknown class”).

In general, over the course of the multiple iterations, the set of classes may be adjusted along with the retraining of the ML classification algorithm. For instance, new classes may be added to the set of classes, based on a respective annotation of the user. Existing classes may be split into multiple classes. Multiple existing classes may be merged into a single class.

This iterative training process can terminate once all anomalies have been classified in the processes and leaving outliers separate class of unknown types. In general, one or more abort criteria may be defined. Example abort criteria are summarized below in TAB. 1.

TABLE 1
Example abort criteria to stop the training process of the ML classification algorithm.
It is possible to cumulatively check for presence of such abort criteria.

| Example | Brief description | Detailed description |
|---|---|---|
| A | User input | A user may manually stops the training |
| | | process, e.g., if the user finds that the |
| | | classification already has an acceptable |
| | | accuracy. |
| B | Number of classes for which | In an exploitative selection of anomalies |
| | anomalies have been | for presentation to the user, it is possible |
| | presented to a user | to present to the user anomalies that have |
| | | been successfully classified by the ML |
| | | classification algorithm into a class of the |
| | | set of classes. It would be possible to |
| | | check whether anomalies have been |
| | | selected from a sufficient fraction of all |
| | | classify the presentation to the user. |
| C | A population of classes in the | For instance, it would be possible to check |
| | current set of classes | whether any class of the current set of |
| | | classes has a significantly smaller count |
| | | of anomalies binned to if compared to |
| | | other classes of the current set of classes. |
| | | Such an inequality may be an indication |
| | | that further training is involved. |
| | | It would alternatively or additionally be |
| | | possible to define for one or more of the |
| | | classes target populations. For instance, |
| | | the target populations could be defined |
| | | based on prior knowledge: for example, |
| | | such prior knowledge may pertain to a |
| | | frequency of occurrence of respective |
| | | defects. To give an example, it would be |
| | | possible that so-called “line brea” |
| | | defects occur significantly less often than |
| | | “line merge” defects; accordingly, it |
| | | would be possible to set the target |
| | | populations of corresponding classes so as |
| | | to reflect the relative likelihood of |
| | | occurrence of these two types of defects. |
| D | A fraction of annotated | It would be possible to check whether a |
| | anomalies | sufficient aggregate number of anomalies |
| | | have been presented to the user and/or |
| | | manually annotated by the user. For |
| | | instance, it would be possible to define a |
| | | threshold of, e.g., 50% or 20% of all |
| | | anomalies detected and then abort the |
| | | iterative training once this threshold is |
| | | reached. |
| E | Probability of finding a new | For example, it would be possible to |
| | class | model the user annotation process. For |
| | | example, it would be possible to predict if |
| | | further annotations would likely introduce |
| | | a new class into the set of classes. For |
| | | example, introduction of new class labels |
| | | can be modeled as a Poisson process. If |
| | | this probability is sufficiently low, the |
| | | process may abort. |
| F | Worst classification - | For example, for all anomalies that have |
| | confidence of the un-annotated | not yet been manually annotated, a |
| | samples exceeds some | confidence level of these anomalies being |
| | minimal confidence | respectively binned into the correct set of |
| | | classes can be determined. The minimum |
| | | confidence level for these anomalies can |
| | | be compared against a threshold and if |
| | | there is no confidence level for the |
| | | unannotated anomalies, this may cause an |
| | | end of the training. |

By such an approach, the manual effort for annotation can be reduced. For example, given that the anomaly detection with N (˜10⁴) anomalies involving C (˜10¹) defect classes, the annotation effort is traditionally O(N). However, with the interactive classification involving G (<<N, ˜10²) groups, it is expected that human annotation effort is reduced to O(G) to discover the C classes.

For illustration, it has been observed that the aggregated count of anomalies selected for presentation to the user can be significantly reduced. For instance, it would be possible that the aggregated count of the anomalies selected for the presentation to the user across the multiple iterations is not larger than 50% of the total count of anomalies.

Further, since batch annotation is possible, the desired annotation effort in the sense of user interaction events can be significantly reduced.

For example, according to various examples, a budget can be defined with respect to the user interactions to perform the annotation to obtain a certain accuracy level (e.g., expressed as precision) for the ML classification algorithm. For instance, the budget could be expressed in a number of clicks in the user interface to obtain a certain precision for the ML classification algorithm.

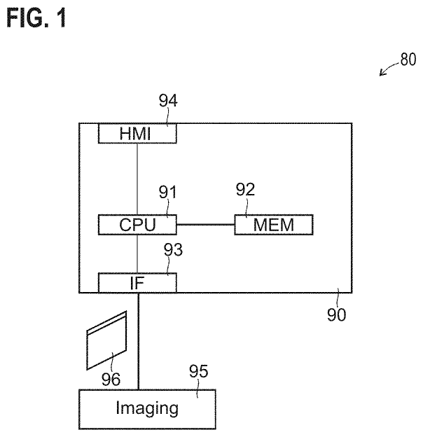

FIG. 1 schematically illustrates a system 80. The system 80 includes an imaging device 95 and a processing device 90. The imaging device 95 is coupled to the processing device 90. The imaging device 95 is configured to acquire imaging datasets of a wafer. The wafer can include semiconductor structures, e.g., transistors such as field effect transistors, memory cells, et cetera. An example implementation of the imaging device 95 would be a SEM or mSEM, a Helium ion microscope (HIM) or a cross-beam device including FIB and SEM or any charged particle imaging device.

The imaging device 95 can provide an imaging dataset 96 to the processing device 90. The processing device 90 includes a processor 91, e.g., implemented as a CPU or GPU. The processor 91 can receive the imaging dataset 96 via an interface 93. The processor 91 can load program code from a memory 92. The processor 91 can execute the program code. Upon executing the program code, the processor 91 performs techniques such as described herein, e.g.: executing an anomaly detection to detect one or more anomalies; training the anomaly detection; executing a classification algorithm to classify the anomalies into a set of classes, e.g., including defect classes, a nuisance class, and/or an unknown class; retraining the ML classification algorithm, e.g., based on an annotation obtained from a user upon presenting at least one anomaly to user, e.g., via respective user interface 94.

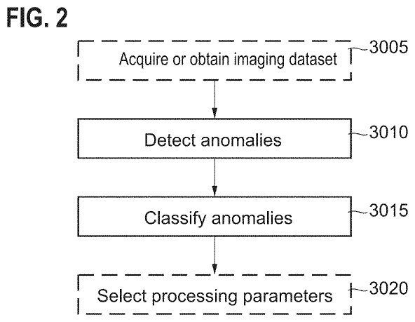

For example, the processor 91 can perform the method of FIG. 2 upon loading program code from the memory 92.

FIG. 2 is a flowchart of a method according to various examples. The method of FIG. 2 can be executed by a processing device for postprocessing imaging datasets. Optional boxes are marked with dashed lines.

At box 3005, an imaging dataset is acquired. Various imaging modalities can be used, e.g., SEM or multi-SEM. In some examples, it would be possible to use multiple imaging modalities to acquire the imaging dataset.

Instead of acquiring the imaging dataset, the imaging dataset may be stored in a database or memory and may be obtained therefrom at box 3005.

At box 3010 a plurality of anomalies are detected in the imaging dataset. This can be based on one or more anomaly detection algorithms. Different types of anomaly detection algorithms are conceivable. For instance, die to die, die to database or an ML anomaly detection algorithm could be used. One example of the ML anomaly detection algorithm implementation includes an autoencoder neural network. In this specific example of the autoencoder neural network, based on a comparison of a reconstructed representation of tile of the imaging dataset with the original tile of the imaging dataset input to the autoencoder neural network, it can be judged whether an anomaly is present in that tile. For instance, a pixel-wise or voxel-wise comparison can be implemented and based on such spatially-resolved comparison, the anomaly may be localized. This would facilitate extracting—in a segmentation of the imaging dataset—a specific tile in which the anomaly a center from the imaging dataset, for further processing at box 3015.

A boundary box may be determined with respect to the detected anomaly, so as to facilitate visual inspection, e.g., in the course of an annotation, by a user.

At box 3015, the anomalies as detected in box 3010 are classified. For example, box 3015 can include two stages: firstly, training of a ML classification algorithm; secondly, inference to classify the anomalies based on the trained ML classification algorithm.

Various techniques are described herein that facilitate accurate training of the ML classification algorithm for subsequent use, e.g., during a production phase in which multiple wafers are produced including respective dies. During the production phase, the trained ML classification algorithm can be used for inference. The manual user interaction during the training phase should be limited. The manual user interaction during the production phase can be further reduced if compared to the training phase. For instance, during the production phase, inference using the trained ML classification algorithm can be used to determine, e.g., a defect count per die and per class. Process monitoring can be implemented, e.g., tracking such defect count.

A classification of the anomalies can yield a binning of the anomalies into a set of classes. The set of classes can include one or more defect classes associated with different types of defects of the semiconductor structures, one or more nuisance classes associated with nuisance or even different types of nuisance such as imaging artefacts vs. process variations vs. particles such as dust deposited on the wafer, etc. These classes can also include a further class including unknown anomalies that cannot be matched with sufficient accuracy to any remaining class of the set of classes.

Then, at box 3020, the classified anomalies, for example the classified defects, may be analyzed by an expert. Alternatively or additionally, automated postprocessing steps are conceivable. For instance, it would be possible to determine quantified metrics associated with the defects, e.g., defect density, defect size, spatial defect distribution, spatial defect density, etc., to give just a few examples.

For illustration, it would be possible to determine the defect density for multiple regions of the wafer based on the result of the ML classification algorithm. Different ones of these regions can be associated with different process parameters of a manufacturing process of the semiconductor structures. This can be in accordance with a Process Window Qualification sample. Then, the appropriate process parameters can be selected based on the defect densities, by concluding which regions show best behavior.

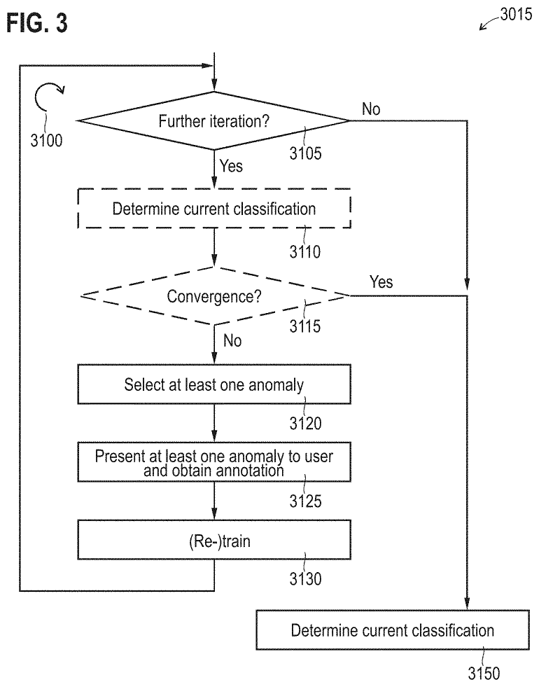

Next, details with respect to the classifying of box 3015 will be explained in connection with FIG. 3.

FIG. 3 is a flowchart illustrating an example implementation of box 3015 of FIG. 2. FIG. 3 illustrates aspects of an iterative and interactive training of a classification algorithm. Multiple iterations 3100 of boxes 3105, 3110, 3115, 3120, 3125, and 3130 can be executed. Optional boxes are illustrated using dashed lines.

Initially, it is checked whether to do a further iteration 3100, at box 3105. For instance, one or more abort criteria as discussed in connection with TAB. 1 could be checked.

If a further iteration 3100 is to be done, the method commences at box 3110. At box 3110, a current classification of the anomalies is determined. For this, it is possible to use the ML classification algorithm in its current training state to determine the current classification. The current training state could rely on pre-training based on further imaging data. The further imaging dataset can depict a further wafer comprising further semiconductor structures which share one or more features with the semiconductor structures of the wafer depicted by the particular imaging dataset including anomalies to be classified. Thereby, such pre-training of the ML classification algorithm may have a certain relevance. The current training state could rely on training of previous iterations 3100.

It is not required in all iterations to execute box 3110. For instance, executing box 3110 can pose a challenge for the first iteration 3100. Here, it would be possible to rely on an unsupervised clustering based on a similarity measure. For example, a pixel-wise similarity between the tiles depicting the anomalies may be determined. Then, different clusters of anomalies having a high similarity measure may be defined. “High similarity” can mean that the similarity is higher than a predetermined threshold.

At optional box 3115, it is possible to check whether convergence has been reached. This can be based on the current classification determined 3110, if available. Again, one or more abort criteria as discussed in connection with TAB. 1 could be checked.

Next, at box 3120, at least one anomaly is selected from the plurality of anomalies previously detected at box 3010. The at least one anomaly selected at box 3120 is then presented to the user at box 3125 and the user provides an annotation for the at least one anomaly.

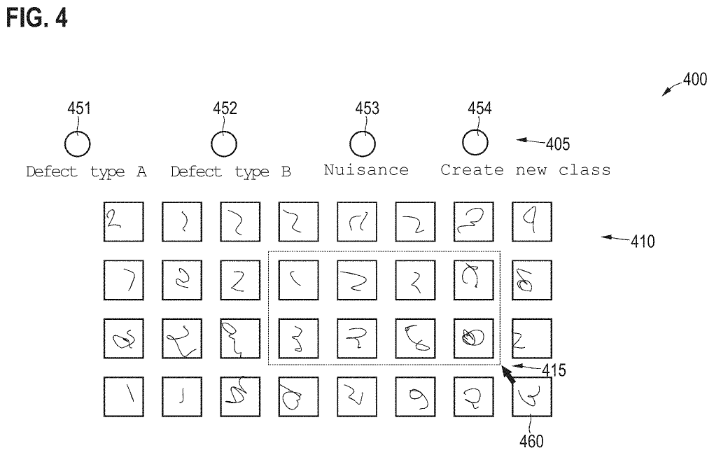

In general, it would be possible that—per iteration 3100—a single anomaly is selected; it would also be possible that multiple anomalies are selected. For example, in a scenario in which multiple anomalies are selected per iteration 3100, it would be possible to concurrently present the multiple anomalies to the user. For illustration, this can include a graphic interface in which an array of tiles including the multiple anomalies are arranged as presented to the user. The multiple anomalies concurrently presented to the user can enable batch annotation. For instance, the user may click and select two or more of the multiple anomalies and annotate them with a joint action, e.g., drag-and-drop into a respective folder associated with the label to be assigned. A respective graphical interface as illustrated in FIG. 4.

FIG. 4 schematically illustrates a graphical interface 400, e.g., as presented on a computer screen, to facilitate presentation of anomalies to the user and to facilitate annotation of the anomalies by the user. The graphical interface 400 includes a section 410 in which the tiles 460 (in the illustrated example, a number of 32 tiles as illustrated, each tile depicting a respective anomaly) of the imaging dataset are presented to the user. A user can batch annotate multiple of these anomalies, e.g., in the illustrated scenario by selecting, using a cursor 415, multiple tiles or simply click on one of the defined defect classes icons to assign all anomalies currently presented to the user to that class with a single click.

In general, it would be possible that the anomalies are presented batch-wise. I.e., from all anomaly selected at box 3120, multiple batches may be determined and these batches can be concurrently presented to the user for the annotation. Such batches may be determined based on an unsupervised clustering based on a similarity measure. It would alternatively or additionally also be possible that the anomalies selected at box 3120 are sorted. Again, this can be based on unsupervised clustering based on a similarity measure.

Then, the user can drag-and-drop the one or more selected tiles/anomalies into a respective bin that is depicted in a section 405 of the graphical interface 400. Each is associated with a respective class 451-454 of the current classification. It would also be possible to create a new class 454 (sometimes labelled as open-set classification).

It has been found that in the context of such batch annotation, it can be helpful to use a ML classification algorithm that can handle uncertainties in the labels annotated by the user. Such labels are sometimes referred to as weak labels, because they can include uncertainty. For example, where a batch of anomalies is annotated in one go, it is possible that unintentional errors in the annotation occur. It would also be possible that the user intentionally assigns multiple labels to a batch of anomalies, wherein for each anomaly of the batch of anomalies one of these multiple labels is applicable. Thus, there can be labelling noise in annotated samples, i.e., erroneous labels annotated by the user. For example, given anomaly group {a1, a2, a3, a4}, the user might annotate {a1: class1, a2: class1, a3: class1, a4: class2}. A further reduction of annotation effort can be achieved by batch assigning a plurality of labels to a batch of anomalies. I.e., for a given batch of anomalies, the user only selects valid classes present in the group (instead of annotating every single anomaly with the correct class label). For example, given the same anomaly group as above, the user would annotate {class1, class2}. The underlying ML classification algorithm can then deal with this intentional label uncertainty.

By relying on such concurrent presentation of multiple anomalies to the user, annotation can be implemented in a particularly fast manner. For example, if compared to a one by one annotation in which multiple anomalies are sequentially presented to the user, batch annotation can significantly speed up the annotation process.

On the other hand, to facilitate such batch annotation, it is typically desirable to select the anomalies to be concurrently presented to the user so that there is a significant likelihood that a significant fraction of the anomalies concurrently presented to the user will be annotated with the same label, i.e., binned to the same class 451-454.

More specifically, by sorting and/or grouping the anomalies, the batch annotation can be further facilitated. For example, it is possible that comparably similar anomalies—thus having a high likelihood of being annotated with the same label—will be arranged next to each other in the graphical interface 400. Thus, the user can easily batch select such anomalies for batch annotation (e.g., using click-drag-select). This is, for example, true if compared to a scenario in which anomalies are arranged in a random order where there is a low likelihood that anomalies presented adjacent to each other to the user would be annotated with the same label. Then, the annotation would result in a manual process where each annotation is individually performed.

Beyond such sorting and/or grouping within the selected anomalies, also the selection of the anomalies at box 3120 can have an impact on the performance of the training process, e.g., in terms of manual annotation effort and/or steep learning curve. Thus, various techniques are based on the finding that the selection of anomalies at box 3120 should consider an appropriate decision criterion.

It is not required in all scenarios that multiple anomalies are selected per iteration 3100 or that multiple anomalies are concurrently presented to the user. Even in a scenario in which a single anomaly are selected per iteration 3100 or in which multiple anomalies are selected per iteration 3100 but sequentially presented to the user, it can be helpful to consider an appropriate decision criterion for selecting the at least one anomaly. Namely, various techniques are based on the finding that the selection of the at least one anomaly at box 3120—referring again to FIG. 3—based on which the annotation is obtained at box 3125 can play a decisive role in a fast and accurate training of the ML classification algorithm.

Accordingly, it is possible to consider one or more decision criteria in the selection of the at least one anomaly at box 3120. These one or more decision criteria are designed to full-fil multiple goals: (i) to provide a steep learning curve in the iterative training process of the ML classification algorithm; (ii) if applicable, enable batch annotation of multiple anomalies concurrently displayed to the user. According to the techniques described herein, decision criteria are provided which help to balance the two goals (i) steep learning curve—(ii) fast batch annotation.

Some examples of such decision criteria that can be considered 3120 to select the at least one anomaly are summarized below in TAB. 2.

TABLE 2
Examples of various decision criteria that can be used in selecting one or more anomalies
to be presented to the user. Such decision criteria can be applied in accumulated manner.
It would be possible that in a scenario in which multiple anomalies fulfil the one or more
decision criteria, these multiple anomalies are concurrently/contemporaneously
presented to the user to facilitate batch annotation. As will be appreciated from the above,
based on the appropriate decision criterion, it is possible to implement explorative
annotation scheme and/or an exploitative annotation scheme and/or a legal refinement
annotation scheme.

| Example | Brief description | Detailed description |
|---|---|---|
| A | High similarity measure | It would be possible to determine a similarity |
| | between multiple | measure between multiple anomalies selected at |
| | anomalies | box 3120 for presentation to the user at box |
| | | 3125. For instance, it would be possible to select |
| | | clusters of similar anomalies, i.e., such anomalies |
| | | that have a high similarity measure between |
| | | each other. |
| | | In general, similar anomalies may be such |
| | | anomalies which graphically have a similar |
| | | appearance. Similar anomalies may be such |
| | | anomalies which are embedded into a similar |
| | | surrounding of the semiconductor structures. |
| | | In general, to determine the similarity between |
| | | the anomalies, an unsupervised clustering |
| | | algorithm may be executed. The clustering |
| | | algorithm may perform a pixel-wise comparison |
| | | between the tiles depicting multiple anomalies. |
| | | Such decision criterion is even possible where, |
| | | e.g., in a first iteration 3100, no classification is |
| | | available, but only a similarity measure. |
| | | Thereby, a likelihood of such anomalies having a |
| | | high degree of similarity being annotated in the |
| | | same manner is high. Thus, batch annotation (as |
| | | explained in connection with FIG. 4) can be |
| | | facilitated. |
| B | Low similarity measure | As an example a above, it would be possible to |
| | between multiple | determine a similarity measure between multiple |
| | anomalies | anomalies selected at box 3120 for presentation |
| | | to the user at box 3125. It would be possible to |
| | | select anomalies that do not possess a high degree |
| | | of similarity. Thereby, it would be possible to |
| | | select anomalies across the spectrum of |
| | | variability of the anomalies. |
| | | Such decision criterion is even possible where, |
| | | e.g., in a first iteration 3100, no classification is |
| | | available, but only a similarity measure. |
| | | This can facilitate a steep learning curve of the |
| | | ML classification algorithm to be trained. |
| C | Binned into the same | It would be possible that multiple anomalies are |
| | class | selected that are all binned into the same class of |
| | | the set of classes of the current classification |
| | | obtained from an execution of the ML |
| | | classification algorithm. Then, it is possible to |
| | | refine the labels for the anomalies in this class |
| | | (label refinement annotation scheme). Label |
| | | refinement can pertain to an annotation scheme in |
| | | which anomalies that already have annotated labels |
| | | (e.g., annotated manually by the user) are selected |
| | | for presentation to the user for annotating, so that |
| | | the labels can be refined, e.g., further subdivided. |
| | | Such a scenario may be, for example, helpful in |
| | | combination with the further decision criterion |
| | | according to example B. For instance, where |
| | | multiple anomalies are binned into the same |
| | | defect class, it may be helpful to refine the labels |
| | | within that defect class. |
| | | Such a scenario, the other hand, may also be |
| | | helpful in combination with the further decision |
| | | criterion according to example A. For instance, |
| | | where multiple anomalies are binned into the |
| | | unknown class, it may be helpful to explore such |
| | | anomalies not yet covered by the ML classification |
| | | algorithm based on clusters of similar anomalies |
| | | within the unknown class. |
| D | Similarity measure of | In general, the similarity measure of the selected |
| | the selected at least one | at least one anomaly and one or more further |
| | anomaly and one or | anomalies previously selected can be high or low. |
| | more further anomalies | For instance, it would be possible to select such |
| | having been selected | one or more anomalies at a given iteration 3100 |
| | in a previous iteration | that are dissimilar to anomalies selected in one |
| | of the multiple | or more proceeding iterations 3100. This can |
| | iterations | help to explore the variability of anomalies |
| | | encountered (explorative annotation scheme). The |
| | | explorative annotation scheme, in general, can |
| | | pertain to selecting anomalies (for annotation by |
| | | the user) that have not been previously annotated |
| | | with labels (e.g., manually by the user) and |
| | | which are dissimilar to such samples that have |
| | | been previously annotated. |
| | | Thereby, the variability of the spectrum of |
| | | anomalies can be efficiently traversed, facilitating |
| | | a steep learning curve of the ML classification |
| | | algorithm to be trained. |
| | | For example, such a scenario can be helpful in |
| | | combination with the decision criterion according |
| | | to example A. I.e., it would be possible that |
| | | the multiple anomalies are selected to have a low |
| | | similarity measure with respect to the one or |
| | | more further anomalies having been previously |
| | | selected, but have a high similarity measure |
| | | between each other. Thus, the selection can be |
| | | implemented such that the classification algorithm |
| | | is used to identify batches of similar anomalies |
| | | most distinct from the anomalies annotated so far |
| | | and those batches are presented for annotation |
| | | before batches of anomalies similar to the ones |
| | | annotated so far. |
| | | This helps to concurrently achieve the effects |
| | | outlined above, i.e. (i) a steep learning curve of |
| | | the ML classification algorithm, as well as (ii) |
| | | facilitating batch annotation, thereby lowering |
| | | the manual annotation effort. |
| | | It would also be possible to select such anomalies |
| | | which have a high similarity measure with |
| | | previously selected anomalies. This corresponds |
| | | to an exploitative annotation scheme. An |
| | | exploitative annotation scheme can, for example, |
| | | pertain to selecting anomalies for presentation to |
| | | the user which have not been annotated with labels |
| | | (e.g., have not been manually annotated by the |
| | | user), and which have a similar characteristic to |
| | | previously annotated samples. Such similarity |
| | | could be determined by unsupervised clustering |
| | | or otherwise, e.g., also relying on the anomalies |
| | | being binned in the same predefined class (cf. |
| | | example E below). |
| E | Binned into a | It would be possible to select a class of the set of |
| | predefined class | classes of the current classification and then |
| | | select one or more anomalies from that predefined |
| | | class. The class of the set of classes could be |
| | | selected based on previously selected classes, i.e., |
| | | subject to the annotation in a previous iteration |
| | | 3100. This can correspond to an exploitative |
| | | annotation scheme implemented by the at least |
| | | one decision criterion. |
| | | For instance, where there are a number of classes |
| | | and the set of classes and previously anomalies |
| | | have been selected from some of these classes, |
| | | then it is possible to select another class of the |
| | | set of classes. |
| | | Thereby, it is possible to exploit the variability |
| | | of the spectrum of classes in the annotation. A |
| | | steep learning curve can be ensured. |
| F | Population of the class | For illustration, it would be possible to select the |
| | of the set of classes | at least one anomaly from such a class that has a |
| | into which the at least | smallest or largest population of compared to |
| | one anomaly is binned | other classes of the set of classes. This helps to |
| | | efficiently tailor the exploitative annotation |
| | | scheme. |
| G | Context of the selected | For example, beyond considering the anomaly |
| | at least one anomaly | itself, it would be possible to consider the context |
| | with respect to the | of the anomaly with respect to the semiconductor |
| | semiconductor | structures. For instance, it would be possible to |
| | structures | select anomalies that are occurring at a position |
| | | of a certain type of semiconductor structure. For |
| | | example, it would be possible to select anomalies |
| | | that occur at certain semiconductor devices |
| | | formed by multiple semiconductor structures. |
| | | For illustration, it would be possible to select all |
| | | anomalies - e.g., across multiple classes of the |
| | | current set of classes of the current classification |
| | | - that are occurring at memory chips. For example, |
| | | it would be possible to select anomalies that |
| | | are occurring at gates of transistors. For instance, |
| | | it would be possible to select anomalies that are |
| | | occurring at transistors. As will be appreciated, |
| | | different hierarchy levels of semiconductor |
| | | structures associated with different length scales |
| | | can be considered as context. In general, a context |
| | | can be considered that occurs at a different |
| | | length scale than the length scale of the anomaly |
| | | itself. For instance, if the anomaly is a size of 10 |
| | | nm, it would be possible to consider a context |
| | | that is on the length scale of 100 nm or 1 μm. |
| | | For instance, it would be possible that the |
| | | respective tiles depicting the anomalies are |
| | | appropriately labelled. |
| | | Such techniques are based on the finding that |
| | | oftentimes the type of the defect, and as such the |
| | | binning into a defect class by the annotation, will |
| | | depend on the context of the semiconductor |
| | | structure. For instance, a gate oxide defect is |
| | | typical there the context gate of a field-effect |
| | | transistor, whereas a broken interconnection |
| | | defect can occur in various kinds of |
| | | semiconductor structures. |

In general, it would be possible that the decision criterion is changed between iterations to 3100. For instance, it would be possible to toggle back and forth between a decision criterion that implements an explorative annotation scheme and a further decision criterion that implements an exploitative annotation scheme. For example, it would be possible to select in a first iteration a decision criterion according to example A and in a second iteration select a decision criterion according to example B.

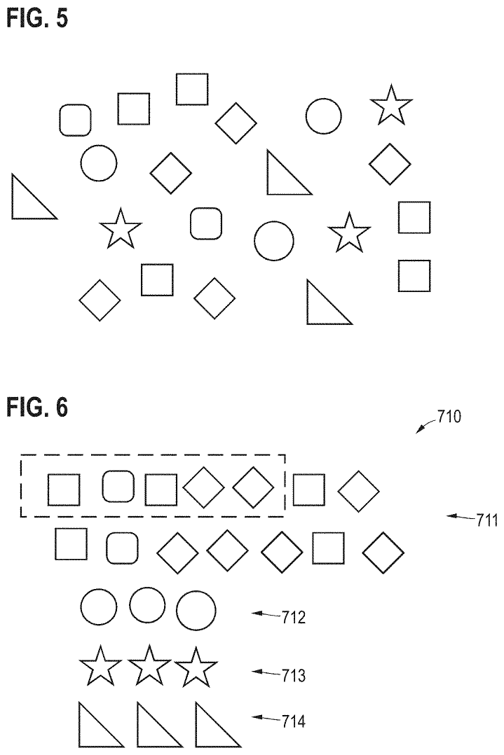

Next, an example implementation of the workflow of FIG. 3 will be explained in connection with FIG. 5-FIG. 11. Furthermore, various decision criteria according to table 2 will be explained in connection with these FIGS.

FIG. 5 illustrates a plurality 700 of anomalies (different types of anomalies are represented by different shapes in FIG. 5: “triangle”, “circle”, “square”, “square with rounded edges”, “star”, “rhomb”).

The first iteration 3100 of box 3110, a set 710 of batches 711-714 is determined based on an unsupervised clustering algorithm based on similarity measures.

Then, multiple anomalies are selected for presentation to the user, based on such unsupervised clustering. These anomalies to be presented are encircled with the dashed line in FIG. 6. As illustrated in FIG. 6, anomalies are selected to be presented to the user that are all in the same batch (cf. TAB. 1: example A), here, specifically the batch with the highest population (somewhat similar to TAB. 1: example F)

The user then provides an annotation of the anomalies presented and the ML classification algorithm is trained at box 3130.

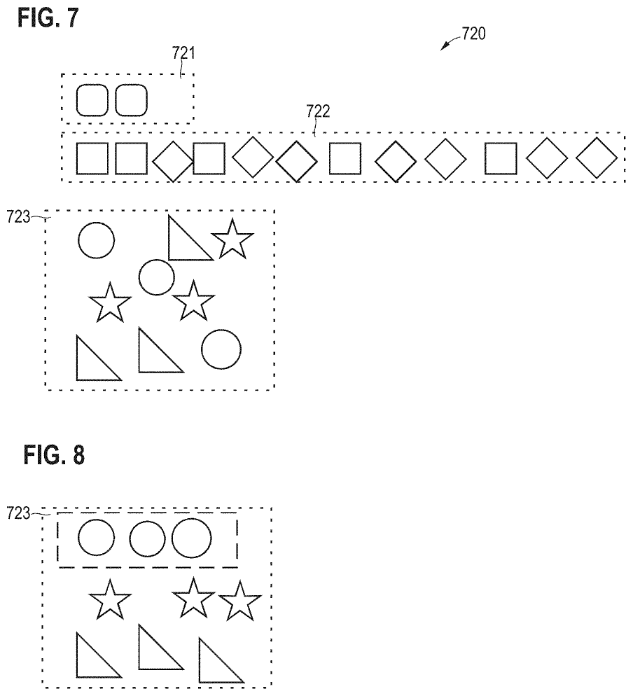

Then, the next iteration 3100 commences and, at box 3110, the trained classification algorithm is executed so as to determine the current classification. The current classification 720 is illustrated in FIG. 7.

The current classification 720 includes a set of classes 721, 722, 723. The class 721 includes the anomalies “square with rounded edges”, and the class 722 includes the anomalies “square” and “rhomb”. As such, training is not completed, because further discrimination between these two types of anomalies would be possible.

The class 723 is a “unknown class”: the ML classification algorithm has not yet been trained based on these anomalies “circle”, “star”, and “triangle” (cf. FIG. 6).

At this iteration of box 3120, an explorative annotation scheme is chosen and, as illustrated in FIG. 8, some of the anomalies in the “unknown class” 763 are selected to be presented to the user (again marked using dashed lines). For example, anomalies are selected that have high similarity, i.e., here also “circle” anomalies. This corresponds to a combination of TAB. 2: examples A and C and D. This helps to concurrently achieve the effects outlined above, i.e. (i) a steep learning curve of the ML classification algorithm, as well as (ii) facilitating batch annotation, thereby lowering the manual annotation effort.

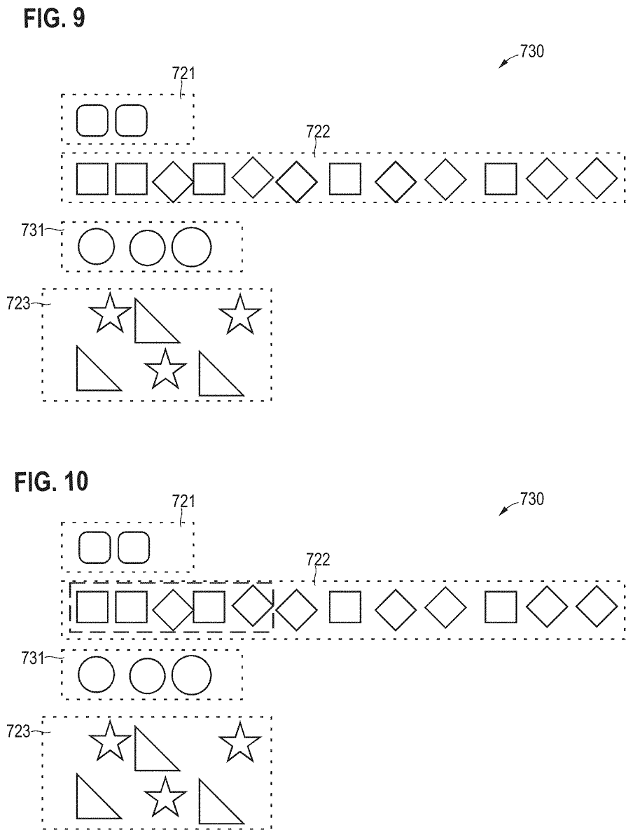

The user can then perform batch annotation of the anomalies “circle” and bin them into a new class 731 of the next classification 740 of the next iteration 3100, cf. FIG. 9.

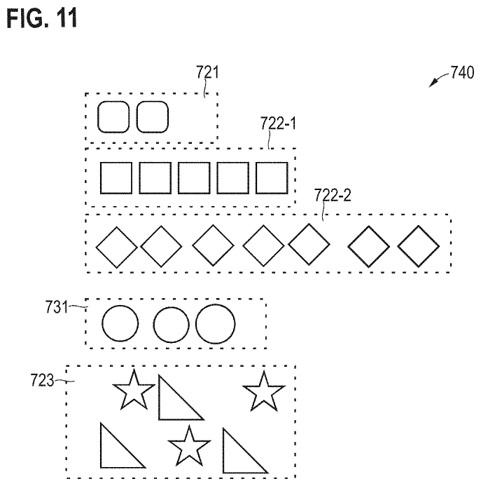

FIG. 10 then illustrates an exploitative annotation scheme where anomalies from the class 722 are selected (illustrated by the dashed lines). For example, this could be the case by considering decision criterion TAB. 2: example F—class 722 has a large population. Furthermore, it would be possible to select such members of the class 722 that have a different context (i.e., correspond to squares or rhombs rotated by 45° with respect to the neighborhood if compared to the squares), cf. TAB. 2, example G.

This helps to refine the coarse class 722 into the finer classes 722-1, 722-2, cf. FIG. 11, in the next iteration 3100 yielding the classification 740.

In FIG. 11, the unknown class 723 still has members in the process can accordingly continue. It would also be possible to check for one or more abort criteria.

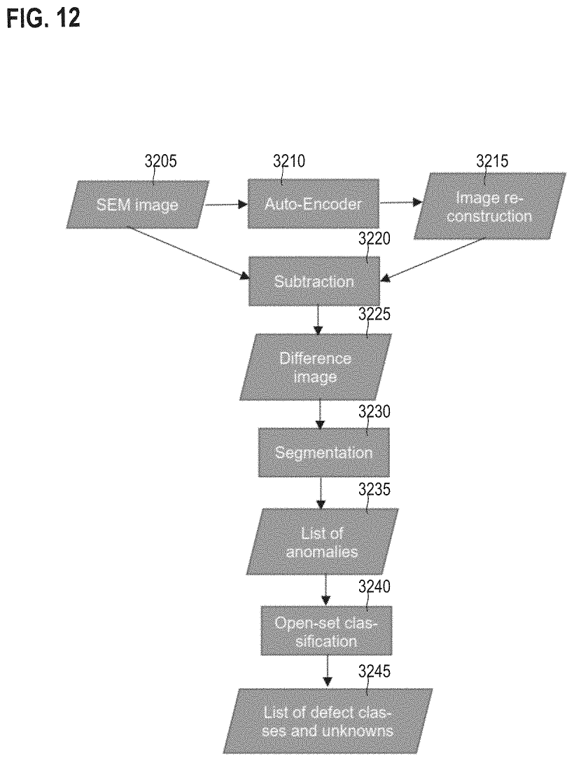

FIG. 12 is a flowchart of a method according to various examples. For example, the method of FIG. 12 could be executed by the processing device 90 of FIG. 1. For instance, the method of FIG. 12 could be implemented by the processor 91 upon loading program code from the memory 92.

The method of FIG. 12 can implement the method of FIG. 2.

At box 3205, a SEM image is obtained, here implementing an imaging data set. The SEM image is then provided to an autoencoder at box 3210 that has been pre-trained. A reconstructed representation of the input image is obtained at box 3215 and can be compared to the original input image of box 3205, at box 3220. This comparison, e.g., implemented as a subtraction in a pixel-wise manner, yields a difference image at box 3225. Areas of high difference can correspond to anomalies. Accordingly, boxes 3205-3225 implement box 3010 of the method of FIG. 2.

At box 3230, the SEM image obtained at box 3205 can be segmented. Multiple tiles can be extracted that are centered around the anomalies detected as peaks in the difference image of box 3225.

Then, a library of anomalies can be obtained as a respective list at box 3235.

The iterative classification, here implemented as an open-set classification, can then commence at box 3240. This corresponds to box 3015.

An example implementation of a respective ML classification algorithm to provide an open-set classification is described in Bendale, Abhijit, and Terrance E. Boult. “Towards open set deep networks.” Proceedings of the IEEE conference on computer vision and pattern recognition. 2016.

At box 3245, a list of defects and nuisance/unknowns is obtained, e.g., corresponding to the classes 721, 722-1, 722-2, 731 and 723 of FIG. 11, respectively.

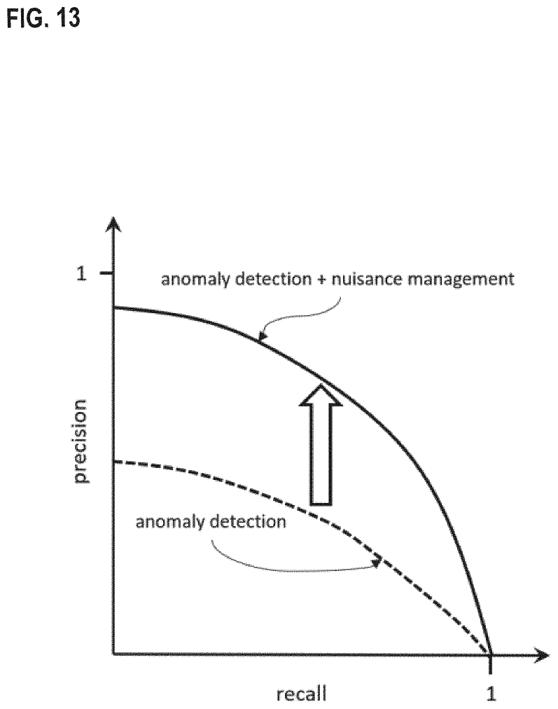

FIG. 13 illustrates an effect of the techniques that have been described above. FIG. 13 plots the precision as the functional recall. Precision defines how many of the detections a real defects. The nuisance equals 1 minus precision. The recall specifies how many defects can be detected. The precision is given by the number of true positives divided by the sum of true positives plus false positives. Differently, the recall is given by the number of true positives divided by the sum of true positives and false negatives.

As illustrated in FIG. 13 by the dashed line, if only anomalies were detected at box 3010 FIG. 2, then a comparably low precision would be obtained. By implementing the additional classification of box 3015, a significantly higher precision can be obtained, as a function of the recall.

An analysis as in FIG. 13 can be based on prior knowledge on the “defect” classes, as a subset of all anomalies (also including nuisance), as ground truth.

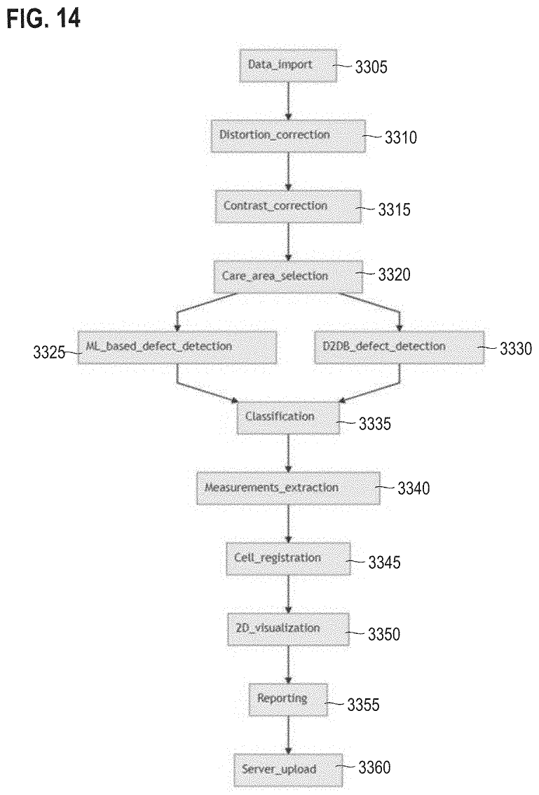

FIG. 14 is a flowchart of a method according to various examples. The method of FIG. 14 can be associated with the workflow of processing of an imaging data set. The method of FIG. 14 can include the method of FIG. 2, at least in parts.

At box 3305, an imaging data set is obtained/imported or acquired. As such, box 3305 can correspond to box 3005 of FIG. 2.

At box 3310, optionally a distortion correction to the charged particle imaging device images is applied. For example, a technique as described in WO 2020/070156 A1 could be applied. For example, a rigid transformation can be applied to the imaging data set. The imaging data set can be skewed and/or expanded and/or contracted and/or rotated.

At box 3315, the contrast of pixels or voxels of the imaging data set can be adjusted. For instance, the contrast may be adjusted with respect to a medium value or a histogram of contrast may be stretched or compressed to cover a certain predefined dynamic range.

At box 3320, a sub-area of the entire imaging data set may be selected. Non-selected areas may be cropped. Thereby, the file size can be reduced.

Box 3315 and 3220 thus correspond to preconditioning of the imaging dataset.

At box 3325 and/or box 3330, one or more anomaly detection algorithms may be executed. For instance, an MLA anomaly detection algorithm may be executed at box 3325 and a conventional anomaly detection algorithm may be executed at box 3330. Box 3325 and 3330 thus implement box 3010, respectively.

At box 3335, a classification of the anomalies detected at box 3325 and/or box 3330 can be determined. Box 3335 thus implements box 3015.

At box 3340, the classification obtained from box 3335 can then be analyzed. One or more measurements can be implemented based on the classification. For example, defects can be quantified, e.g., by determining the size, the spatial density of defects, etc.

At box 3345, locations of the defects obtained in one or more defect classes of the classification can be registered to certain cells of a predefined gridding superimposed on the imaging data set.

At box 3350, a visualization of the defect density is then possible, e.g., based on such registration of the defects to the gridding. For example, the defect density can be color coded.

At box 3355 a reporting can be implemented. For instance, a written report can be implemented or an API to a production management system can be access.

It would be possible that such report is then uploaded at box 3360.

Although the disclosure has been shown and described with respect to certain preferred embodiments, equivalents and modifications will occur to others skilled in the art upon the reading and understanding of the specification. The present disclosure includes all such equivalents and modifications and is limited only by the scope of the appended claims.

For illustration, various examples have been described in the context of an imaging data set depicting a wafer including semiconductor structures. However, similar techniques may be readily applied to other kinds and types of information content to be subject to anomaly detection and classification.

What is claimed is:

1. A method, comprising:
detecting a plurality of anomalies in an imaging dataset of a wafer, the wafer comprising a plurality of semiconductor structures; and
executing multiple iterations, at least some iterations of the multiple iterations comprising:
determining a current classification of the plurality of anomalies using a machine-learned classification algorithm and tiles of the imaging dataset associated with the plurality of anomalies, the current classification comprising a current set of classes into which the anomalies of the plurality of anomalies are binned;
based on at least one decision criterion, selecting at least one anomaly of the plurality of anomalies for presentation to a user; and
based on an annotation of the at least one anomaly provided by the user with respect to the current classification, re-training the classification algorithm.

2. The method of claim 1, wherein the at least one anomaly comprises multiple anomalies, and the at least one decision criterion comprises a similarity measure between the multiple anomalies.

3. The method of claim 2, further comprising selecting the multiple anomalies to have a high similarity measure between each other.

4. The method of claim 1, wherein the at least one decision criterion comprises a similarity measure of the selected at least one anomaly and one or more further anomalies that were selected in a previous iteration of the multiple iterations.

5. The method of claim 4, further comprising selecting the multiple anomalies to have a low similarity measure with respect to the one or more further anomalies that were selected in the previous iteration of the multiple iterations.

6. The method of any one of claim 1, wherein the at least one anomaly comprises multiple anomalies, and the at least one decision criterion comprises the multiple anomalies being binned into the same class of the current set of classes.

7. The method of claim 6, wherein the same class comprises at least one of an unknown class or a defect class.

8. The method of claim 1, wherein the at least one decision criterion comprises the selected at least one anomaly being binned into a predefined class of the set of classes.

9. The method of claim 1, wherein the at least one decision criterion comprises a population of a class of the set of classes into which the at least one anomaly is binned.

10. The method of any one of claim 1, wherein the at least one decision criterion comprises a context of the selected at least one anomaly with respect to the semiconductor structures.

11. The method of claim 1, wherein the at least one decision criterion implements at least one member selected from the group consisting of an explorative annotation scheme and an exploitative annotation scheme.

12. The method of claim 1, wherein the at least one decision criterion differs for at least two iterations of the at least some iterations.

13. The method of claim 1, wherein an aggregated count of the anomalies selected for presentation to the user across the multiple iterations is at most 50% of a count of the plurality of iterations.

14. The method of claim 1, wherein the annotation of the at least one anomaly comprises a new class to be added to the current set of classes.

15. The method of claim 1, further comprising, in a first iteration of the multiple iterations, performing an unsupervised clustering of the plurality of anomalies,
wherein the at least one anomaly is selected based on the unsupervised clustering.

16. The method of claim 1, further comprising aborting execution of the multiple iterations based on at least one abort criterion,
wherein the abort criterion is selected from the group consisting of a user input, a number of classes for which anomalies have been presented to the user, a population of classes in the current set of classes, a probability of finding a new class not yet included in the set of classes, a worst classification confidence of all un-annotated anomalies, and an aggregated count of anomalies selected for presentation to the user or annotated by the user reaching a threshold.

17. The method of claim 1, wherein the at least one anomaly comprises multiple anomalies concurrently presented to the user, the method further comprises using a user interface to present to the user, and the user interface is configured to batch annotate the multiple anomalies.

18. The method of claim 17, wherein batch annotation of the multiple anomalies comprises batch assigning of a plurality of labels to the multiple anomalies concurrently presented to the user.

19. The method of claim 1, wherein the at least one anomaly comprises multiple anomalies concurrently presented to the user, and the method further comprises grouping and/or sorting the multiple anomalies to present to the user.

20. The method of claim 1, wherein, for a first iteration of the multiple iterations, the machine-learned classification algorithm is pre-trained based on: i) an imaging dataset of a further wafer comprising further semiconductor structures sharing one or more features with semiconductor structures of the plurality of semiconductor structures; or ii) a preclassification using a further classification algorithm.

21. The method of claim 1, further comprising one of the following:
detecting the plurality of anomalies using an autoencoder neural network and based on a comparison between an input tile of the imaging data provided to the autoencoder neural network and a reconstructed representation of the input tile output by the autoencoder neural network; and
detecting the plurality of anomalies using a die-to-die and/or die-to-database registration.

22. The method of claim 1, wherein the tiles of the imaging data comprise the anomalies and a surrounding of the anomalies.

23. The method of claim 1, wherein the current set of classes comprises at least one defect class and at least one nuisance class.

24. The method of claim 1, further comprising determining a defect density for multiple regions of the wafer based on the machine-learned classification algorithm and the plurality of anomalies, wherein different ones of the multiple regions are associated with different process parameters of a manufacturing process of the semiconductor structures.

25. The method of claim 1, wherein the imaging dataset is a multibeam SEM image.

26. The method of claim 1, wherein detecting the plurality of anomalies and the executing of the multiple iterations is part of a work-flow comprising a sequence of:
preconditioning the imaging dataset;
detecting of the plurality of anomalies;
executing of the plurality of iterations;
basing one or more measurements on the classification; and
visualizing and/or reporting.

27. One or more machine-readable hardware storage devices comprising instructions that are executable by one or more processing devices to perform operations comprising the method of claim 1.

28. A system comprising:
one or more processing devices; and
one or more machine-readable hardware storage devices comprising instructions that are executable by the one or more processing devices to perform operations comprising the method of claim 1.
